(19) United States
(12) Patent Application Publication
(10) Pub. No.: US 2025/0075322 A1
(43) Pub. Date: Mar. 6, 2025

(54) METHOD OF MONITORING LIQUID RAW MATERIAL AND GAS SUPPLY DEVICE

(71) Applicant: Tokyo Electron Limited, Tokyo (JP)

(72) Inventors: Takuya HIGUCHI, Iwate (JP); Kosuke TAKAHASHI, Iwate (JP); Yasuhiro ONODERA, Iwate (JP)

(21) Appl. No.: 18/822,332

(22) Filed: Sep. 2, 2024

(30) Foreign Application Priority Data
Sep. 4, 2023 (JP) 2023-143106

(51) Int. Cl. C23C 16/54; C23C 16/06

(52) U.S. Cl. CPC C23C 16/45561; C23C 16/4481

(57) ABSTRACT

A method of monitoring a liquid raw material in a gas supply device, including a raw material storage tank that stores the liquid raw material, a liquid level detector that detects a liquid level of the liquid raw material, a gas inlet provided in the raw material storage tank, a gas outlet provided in the raw material storage tank, and a raw material inlet provided in the raw material storage tank, includes calculating a remaining amount of the liquid raw material based on a usage amount of the raw material and a replenishment amount of the raw material, estimating a detection result of a virtual sensor from the calculated remaining amount of the liquid raw material, and monitoring the liquid raw material based on a detection result of the liquid level detector and the estimated detection result of the virtual sensor.

### CROSS-REFERENCE TO RELATED APPLICATIONS

This application is based on and claims priority from Japanese Patent Application No. 2023-143106, filed on Sep. 4, 2023, with the Japan Patent Office, the disclosure of which is incorporated herein in its entirety by reference.

### TECHNICAL FIELD

The present disclosure relates to a method of monitoring a liquid raw material and a gas supply device.

### BACKGROUND

Japanese Patent Laid-Open Publication No. 2014-007289 discloses a raw material storage tank having a level measuring device that recognizes the liquid level position of a liquid raw material in a stepwise manner.

### SUMMARY

According to one embodiment, there is provided a method of monitoring a liquid raw material in a gas supply device. The gas supply device includes a raw material storage tank that stores the liquid raw material, a liquid level detector that detects a liquid level of the liquid raw material stored in the raw material storage tank, a gas inlet provided in the raw material storage tank and connected to a carrier gas supply that supplies a carrier gas carrying a raw material gas to the raw material storage tank, a gas outlet provided in the raw material storage tank and connected to a gas discharger that discharges the raw material gas, along with the carrier gas, from the raw material storage tank, and a raw material inlet provided in the raw material storage tank and connected to a liquid raw material supply that supplies the liquid raw material to the raw material storage tank. The method includes calculating a remaining amount of the liquid raw material based on a usage amount of the raw material and a replenishment amount of the raw material, estimating a detection result of a virtual sensor from the remaining amount of the liquid raw material calculated in the calculating, and monitoring the liquid raw material based on a detection result of the liquid level detector and the detection result of the virtual sensor estimated in the estimating.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an example of a schematic diagram illustrating a configuration example of a gas supply device.

FIG. 2 is an example of a diagram illustrating the level detection position of a raw material storage tank.

FIG. 3 is an example of a functional block diagram of a liquid amount monitor.

FIG. 4 is a graph illustrating an example of a change in the liquid level of a liquid raw material.

FIG. 5 is a flowchart illustrating an example of a liquid raw material replenishment operation.

FIG. 6 is an example of a display screen displayed on a display.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### [Gas Supply Device]

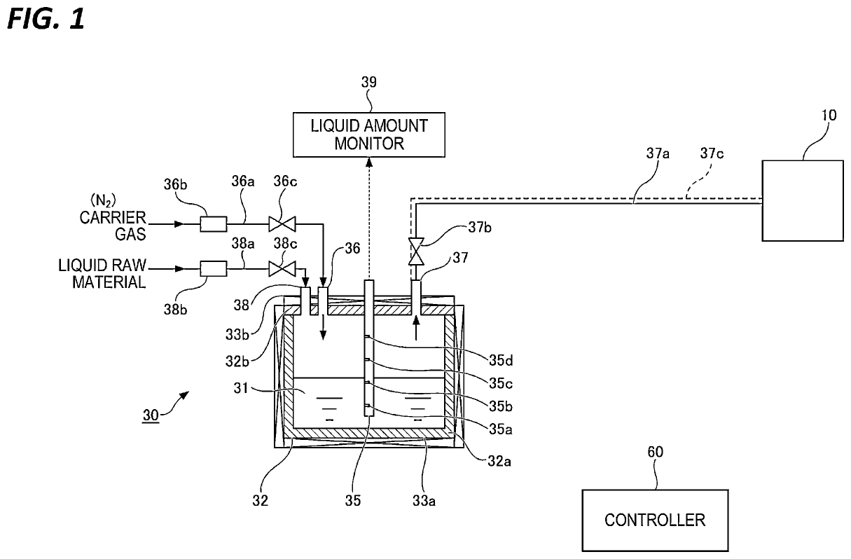

A configuration of a gas supply device 30 according to the present embodiment will be described with reference to FIG. 1. FIG. 1 is an example of a schematic diagram illustrating a configuration example of the gas supply device 30.

The gas supply device 30 is an apparatus that supplies a raw material gas, generated by heating a liquid raw material 31, along with a carrier gas, to a processing container 10 of a substrate processing apparatus. The substrate processing apparatus uses the gases supplied from the gas supply device 30 to perform a desired processing (e.g., film formation) on a substrate inside the processing container 10. The substrate processing apparatus having the processing container 10 may be, for example, a film forming apparatus, and more particularly, a semi-batch type film forming apparatus, which rotates a plurality of substrates placed on a rotary table inside the processing container 10 by rotation of the rotary table, and allows the substrates to sequentially pass through an area to which a first gas (e.g., the raw material gas supplied from the gas supply device 30) is suppled and an area to which a second gas (e.g., a reactive gas that forms a desired film on a substrate surface by reacting with the raw material gas) is supplied, thereby performing film formation on the substrates. In addition, the substrate processing apparatus having the processing container 10 is not limited to the semi-batch type film forming apparatus, but may be, for example, a batch type film forming apparatus that processes a plurality of substrates inside the processing container 10 at once, a single film forming apparatus that processes substrates one by one, or a multiple sheet type film forming apparatus having a plurality of stages inside the processing container 10.

In addition, the liquid raw material 31 may be, for example, a raw material containing at least one of various metals such as aluminum (Al), hafnium (Hf), zirconium (Zr), and titanium (Ti), or a raw material containing silicon (Si). Further, as for the carrier gas, an inert gas such as nitrogen (N₂) gas or a noble gas (e.g., Ar or He) may be used.

The gas supply device 30 includes a raw material storage tank 32 that stores the liquid raw material 31. The raw material storage tank 32 is also referred to as a tank, ampoule, or reservoir. The raw material storage tank 32 include a tank body 32a formed in a bottomed cylindrical shape and a ceiling lid 32b that airtightly covers the ceiling of the tank body 32a. The tank body 32a and the ceiling lid 32b are made of a metal material such as stainless steel. The capacity of this raw material storage tank 32 is set to, for example, about 1 to 10 liters. A lower region inside the raw material storage tank 32 forms a liquid phase region where the liquid raw material 31 is collected. An upper region inside the raw material storage tank 32 forms a gas phase region where the raw material gas is collected. The size of the gas phase region increases or decreases with the vertical displacement of the liquid level of the liquid raw material 31. That is, the size of the gas phase region increases as the liquid level of the liquid raw material 31 falls, whereas the size of the gas phase region decreases as the liquid level of the liquid raw material 31 rises.

The gas supply device 30 includes a heater unit (main heater 33a and ceiling heater 33b) that heats the liquid raw material 31 stored in the raw material storage tank 32 to generate the raw material gas. Specifically, the gas supply device 30 includes the main heater 33a that heats the bottom and lateral side of the raw material storage tank 32 to generate the raw material gas and the ceiling heater 33b that heats the ceiling of the raw material storage tank 32. More specifically, the main heater 33a is provided to surround and cover almost the entire outer peripheral surface of the bottom and lateral side of the tank body 32a. The ceiling heater 33b is provided to cover almost the entire upper surface of the ceiling lid 32b. In addition, the main heater 33a may be provided on a part of the tank body 32a. Further, the ceiling heater 33b may be provided on a part of the ceiling lid 32b.

The gas supply device 30 includes a level sensor 35. The level sensor 35 detects the liquid level of the liquid raw material 31 stored in the raw material storage tank 32. The level sensor 35 includes a rod-shaped level measurement body, which is attached to, for example, the ceiling lid 32b to penetrate it and extends into the raw material storage tank 32, and a plurality of detection sensors 35a to 35d, which detect the presence or absence of the liquid raw material 31 in the longitudinal direction (height direction) of the level measurement body. When the liquid level of the liquid raw material 31 reaches or exceeds the position of each of the detection sensors 35a to 35d, each of the detection sensors 35a to 35d turns ON. When the liquid level of the liquid raw material 31 is below the position of each of the detection sensors 35a to 35d, each of the detection sensors 35a to 35d turns OFF. Accordingly, the level sensor 35 is configured to be able to recognize the liquid level position of the liquid raw material 31 stored in the raw material storage tank 32 in a stepwise manner based on the detection results of the detection sensors 35a to 35d. Detection signals from the level sensor 35 (the detection sensors 35a to 35d) are sent to a liquid amount monitor 39 and a controller 60.

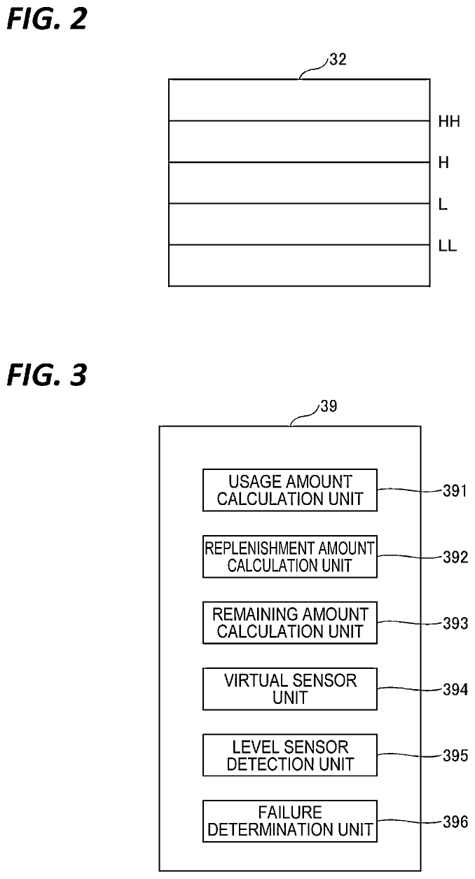

FIG. 2 is an example of a diagram illustrating the level detection position of the raw material storage tank 32. The raw material storage tank 32 illustrated in FIG. 2 has level detection positions “LL,” “L,” “H,” and “HH” from bottom to top. The detection sensor 35a is installed at the level detection position “LL.” The detection sensor 35b is installed at the level detection position “L.” The detection sensor 35c is installed at the level detection position “H.” The detection sensor 35d is installed at the level detection position “HH.”

For example, when the detection sensors 35a to 35d do not detect the liquid raw material (OFF state), it indicates that the liquid level of the liquid raw material 31 is located below the level detection position “LL.”

Further, when the detection sensor 35a detects the liquid raw material (ON state) and the detection sensors 35b to 35d do not detect the liquid raw material (OFF state), it indicates that the liquid level of the liquid raw material 31 is located between the level detection position “LL” and the level detection position “L.”

Further, when the detection sensors 35a and 35b detect the liquid raw material (ON state) and the detection sensors 35c and 35d do not detect the liquid raw material (OFF state), it indicates that the liquid level of the liquid raw material 31 is located between the level detection position “L” and the level detection position “H.”

Further, when the detection sensors 35a to 35c detect the liquid raw material (ON state) and the detection sensor 35d does not detect the liquid raw material (OFF state), it indicates that the liquid level of the liquid raw material 31 is located between the level detection position “H” and the level detection position “HH.”

Further, when the detection sensors 35a to 35d detect the liquid raw material (ON state), it indicates that the liquid level of the liquid raw material 31 is located above the level detection position “HH.”

Returning to FIG. 1, the ceiling lid 32b of the raw material storage tank 32 is provided with a gas inlet 36, a gas outlet 37, and a raw material inlet 38.

The gas inlet 36 is connected to a carrier gas supply that supplies the carrier gas carrying the raw material gas to the raw material storage tank 32. The carrier gas supply includes a carrier gas source (not illustrated), a carrier gas flow path 36a, and a flow rate controller 36b and an opening/closing valve 36c, both of which are interposed in the carrier gas flow path 36a. One end of the carrier gas flow path 36a is connected to the carrier gas source (not illustrated), and the other end is connected to the gas inlet 36.

The gas outlet 37 is connected to a gas discharger that discharges the raw material gas, along with the carrier gas, from the raw material storage tank 32. The gas discharger includes a gas flow path 37a, an opening/closing valve 37b interposed in the gas flow path 37a, and a flow path heater 37c installed to the gas flow path 37a. One end of the gas flow path 37a is connected to the gas outlet 37, and the other end is connected to the processing container 10. The controller 60 may supply the carrier gas, with a controlled flow rate, to the raw material storage tank 32 by opening the opening/closing valves 36c and 37b and controlling the flow rate controller 36b. By supplying the carrier gas with a controlled flow rate into the raw material storage tank 32 through the gas inlet 36, the saturated raw material gas is discharged along with the carrier gas from the gas outlet 37 to the gas flow path 37a. Then, the raw material gas, transferred along with the carrier gas, is supplied into the processing container 10. Further, the controller 60 may stop the supply of the raw material gas to the processing container 10 by closing at least one of the opening/closing valves 36c and 37b. Further, the flow path heater 37c, such as a tape heater, is installed along the gas flow path 37a and serves to heat the gas flow path 37a to approximately 85 to 165° C. to prevent the raw material gas from liquefying.

The raw material inlet 38 is connected to a liquid raw material supply that supplies the liquid raw material to the raw material storage tank 32. The liquid raw material supply includes a liquid raw material source (not illustrated), a liquid raw material flow path 38a, and a flow rate controller 38b and an opening/closing valve 38c, both of which are interposed in the liquid raw material flow path 38a. One end of the liquid raw material flow path 38a is connected to a liquid raw material source (not illustrated), and the other end is connected to the raw material inlet 38. The controller 60 may supply the liquid raw material, with a controlled flow rate, to the raw material storage tank 32 by opening the opening/closing valve 38c and controlling the flow rate controller 38b. Further, the controller 60 may stop the supply of the liquid raw material to the raw material storage tank 32 by closing the opening/closing valve 38c.

The gas supply device 30 includes the liquid amount monitor 39 and the controller 60.

The liquid amount monitor 39 monitors the amount of the liquid raw material 31 stored in the raw material storage tank 32. In addition, the liquid amount monitor 39 will be described later with reference to FIG. 3.

The detection results of the level sensor 35 (detection sensors 35a to 35d) and the results of the liquid amount monitor 39 are input to the controller 60. Further, the controller 60 controls the flow rate of the carrier gas supplied from the carrier gas supply to the raw material storage tank 32 and the flow rate of a mixed gas of the carrier gas and the raw material gas supplied from the raw material storage tank 32 to the processing container 10 by controlling the flow rate controller 36b, the opening/closing valves 36c and 37b, and the like. Further, the controller 60 controls the replenishment amount of the liquid raw material supplied to the raw material storage tank 32 by controlling the flow rate controller 38b, the opening/closing valve 38c, and the like.

The controller 60 may be, for example, a computer. Further, the computer may include a display such as a monitor to display various types of information. Further, a computer program that executes the operation of each component of the gas supply device 30 is stored in a storage medium. The storage medium may be, for example, a flexible disk, compact disk, hard disk, flash memory, or DVD.

Next, the liquid amount monitor 39 will be described with reference to FIG. 3. FIG. 3 is an example of a functional block diagram of the liquid amount monitor 39.

The liquid amount monitor 39 includes a usage amount calculation unit 391, a replenishment amount calculation unit 392, a remaining amount calculation unit 393, a virtual sensor unit 394, a level sensor detection unit 395, and a failure determination unit 396.

The usage amount calculation unit 391 calculates the usage amount of the raw material (raw material gas) supplied from the raw material storage tank 32 to the processing container 10. For example, the usage amount calculation unit 391 calculates the usage amount based on the time for which the raw material is used and coefficients related to the raw material.

The replenishment amount calculation unit 392 calculates the replenishment amount of the raw material (liquid raw material) supplied from the liquid raw material supply (not illustrated) to the raw material storage tank 32. For example, the replenishment amount calculation unit 392 calculates the replenishment amount based on the flow rate during replenishment. Specifically, the replenishment amount calculation unit 392 calculates the replenishment amount based on the flow rate controlled by the flow rate controller 38b and the open time (replenishment time) of the opening/closing valve 38c.

The remaining amount calculation unit 393 calculates the remaining amount (liquid amount) of the liquid raw material 31 stored in the raw material storage tank 32.

Here, the liquid amount monitor 39 (remaining amount calculation unit 393) previously stores information where each level detection position “LL,” “L,” “H,” or “HH” is associated with the amount of the liquid raw material 31 stored in the raw material storage tank 32 up to that level detection position. The remaining amount calculation unit 393 sets the amount of the liquid raw material 31 corresponding to any one of the detection sensors 35a to 35d at the timing when that detection sensor has switched from the ON state to the OFF state or from the OFF state to the ON state as the remaining amount (initial remaining amount value) of the liquid raw material 31 stored in the raw material storage tank 32. Subsequently, the remaining amount calculation unit 393 calculates the remaining amount based on the initial remaining amount value of the liquid raw material 31, the usage amount after the setting of the initial remaining amount value calculated by the usage amount calculation unit 391, and the replenishment amount the setting of the initial remaining amount value calculated by the replenishment amount calculation unit 392 (remaining amount=initial remaining amount value−usage amount+replenishment amount).

The virtual sensor unit 394 includes virtual detection sensors (hereinafter also referred to as “virtual sensors”) at the respective level detection positions “LL,” “L,” “H,” and “HH” and estimates the detection results of the virtual sensors.

The liquid amount monitor 39 (virtual sensor unit 394) previously stores information where each level detection position “LL,” “L,” “H,” or “HH” is associated with the amount of the liquid raw material 31 stored in the raw material storage tank 32 up to that level detection position. The virtual sensor unit 394 estimates the detection results (ON state or OFF state) of the virtual sensor at the level detection position “LL,” the virtual sensor at the level detection position “L,” the virtual sensor at the level detection position “H,” and the virtual sensor at the level detection position “HH” based on the remaining amount of the liquid raw material 31 calculated by the remaining amount calculation unit 393 and this information.

The level sensor detection unit 395 acquires the detection results of the level sensor 35 (detection sensors 35a to 35d, hereinafter also referred to as “actual sensors”). That is, the level sensor detection unit 395 acquires the detection results (ON state or OFF state) of the detection sensor 35a at the level detection position “LL,” the detection sensor 35b at the level detection position “L,” the detection sensor 35c at the level detection position “H,” and the detection sensor 35d at the level detection position “HH.”

The failure determination unit 396 determines the failure of the level sensor 35 (detection sensors 35a to 35d). The failure determination unit 396 determines whether or not the detection results of the virtual sensors estimated by the virtual sensor unit 394 match with the detection results of the actual sensors acquired by the level sensor detection unit 395, and when the results do not match, determines that there is a failure of the level sensor 35 (detection sensors 35a to 35d). Further, the failure determination unit 396 determines the failure of the level sensor 35 (detection sensors 35a to 35d) based on the remaining amount (liquid amount) of the liquid raw material 31 stored in the raw material storage tank 32 calculated by the remaining amount calculation unit 393 and the detection results of the actual sensors acquired by the level sensor detection unit 395.

In this way, the gas supply device 30 according to the present embodiment may double monitor the liquid level of the liquid raw material 31 stored in the raw material storage tank 32 by using both the level sensor 35 (detection sensors 35a to 35d), which is an actual sensor, and the virtual sensor unit 394, which is a virtual sensor.

Further, the remaining amount calculation unit 393 of the gas supply device 30 according to the present embodiment may appropriately calculate the remaining amount (liquid amount) of the liquid raw material 31 stored in the raw material storage tank 32 even when the liquid level is between one level detection position and another level detection position, or even when the liquid level is below the level detection position “LL.” This allows the gas supply device 30 according to the present embodiment to accurately monitor the remaining amount (liquid amount) of the liquid raw material 31.

Further, the failure determination unit 396 of the gas supply device 30 according to the present embodiment may determine the failure of the level sensor 35 (detection sensors 35a to 35d) by comparing the detection results of the virtual sensors with the detection results of the actual sensors (detection sensors 35a to 35d). When the failure determination unit 396 determines that there is a failure of the level sensor 35 (detection sensors 35a to 35d), the controller 60 displays this information on a display (not illustrated) such as a monitor. This allows an operator to be informed of the failure of the level sensor 35 (detection sensors 35a to 35d).

In addition, when the failure of the level sensor 35 (detection sensors 35a to 35d) is determined using only the actual sensors (detection sensors 35a to 35d), it may be determined that a target detection sensor has failed, for example, when the detection results of the target detection sensor remains in the ON state even though the liquid level of the liquid raw material 31 has dropped below the level detection position of the target detection sensor due to the sufficient use of the liquid raw material 31, or when the detection result of the target detection sensor remains in the OFF state even though the liquid level of the liquid raw material 31 has risen above the level detection position of the target detection sensor due to the sufficient replenishment of the liquid raw material 31. Therefore, there is a risk that determining the failure of a detection sensor may take a considerable amount of time.

In contrast, the failure determination unit 396 of the gas supply device 30 according to the present embodiment is capable of rapidly determining the failure of the detection sensors 35a to 35d since it may determine the failure of the detection sensors 35a to 35d by comparing the detection results of the virtual sensors with the detection results of the actual sensors (detection sensors 35a to 35d).

Further, according to the gas supply device 30 of the present embodiment, the volume of the gas phase region may be appropriately managed by monitoring the liquid level. This may improve the uniformity of substrate processing in the substrate processing apparatus.

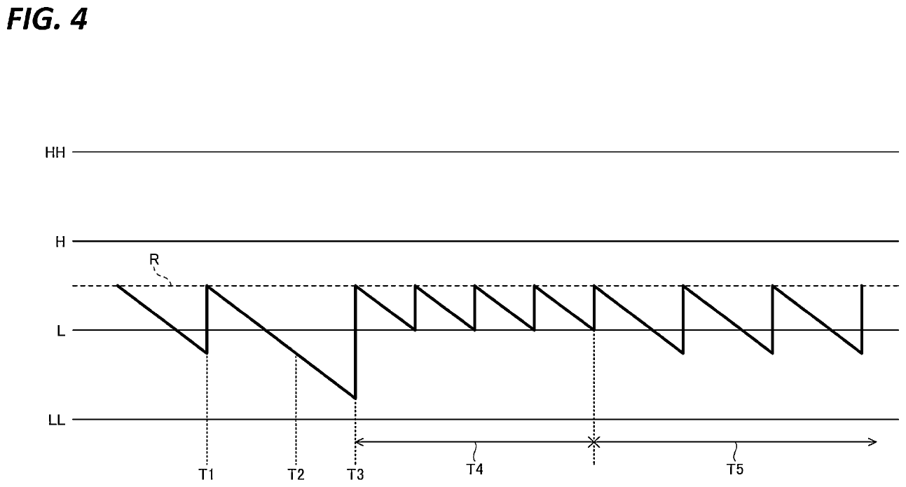

Next, an example of the operation of the gas supply device 30 will be described with reference to FIG. 4. FIG. 4 is a graph illustrating an example of a change in the liquid level of the liquid raw material 31. In FIG. 4, the vertical axis represents the liquid level, and the horizontal axis represents time. “LL,” “L,” “H,” and “HH” indicate the level detection positions where the detection sensors 35a to 35d are installed. Further, “R” represented by the dashed line indicates a target liquid level (hereinafter also referred to as “reference level”) when replenishing the raw material storage tank 32 with the liquid raw material.

By supplying a vaporized raw material gas to the processing container 10, the liquid level of the liquid raw material 31 gradually decreases. At time T1, the replenishment timing for the liquid raw material is reached. Here, the replenishment timing is determined using the actual sensors (detection sensors 35a to 35d). For example, the replenishment timing is determined after the detection sensor 35b changes from the ON state to the OFF state.

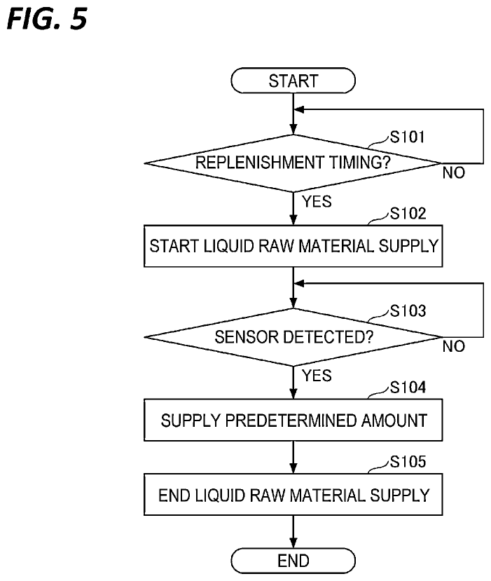

Here, an example of a liquid raw material replenishment operation using the actual sensors will be described with reference to FIG. 5. FIG. 5 is a flowchart illustrating an example of the liquid raw material replenishment operation.

In step S101, the controller 60 determines whether or not it is the replenishment timing. When it is not the replenishment timing (S101·NO), the controller 60 repeats the processing of step S101. When it is the replenishment timing (S101·YES), the controller 60 proceeds to step S102.

In step S102, the controller 60 starts supplying the liquid raw material. The controller 60 controls the flow rate controller 38b to a predetermined flow rate and controls the opening/closing valve 38c to be open, thereby supplying the liquid raw material from the liquid raw material supply (not illustrated) to the raw material storage tank 32.

In step S103, the controller 60 determines whether or not the detection sensor 35b has detected the liquid raw material. In other words, the controller 60 determines whether or not the determination results of the detection sensor 35b has switched from the OFF state to the ON state. When the detection sensor 35b has not detected the liquid raw material (S103·NO), the controller 60 repeats the processing of step S103 to continue the replenishment of the liquid raw material. When the detection sensor 35b has detected the liquid raw material (S103. YES), the controller 60 proceeds to step S104.

In step S104, the controller 60 supplies the liquid raw material at a predetermined flow rate. Here, the predetermined flow rate is the amount of liquid raw material required to reach the reference level “R” from the level detection position “LL.” The controller 60 supplies a predetermined amount of liquid raw material based on the flow rate controlled by the flow rate controller 38b and the time. Once the predetermined amount of liquid raw material has been supplied, the controller 60 proceeds to step S105.

In step S105, the controller 60 terminates the supply of the liquid raw material. In other words, the controller 60 controls the opening/closing valve 38c to be closed.

Through the above processing, as illustrated at time T1 in FIG. 4, the liquid level of the liquid raw material 31 is replenished until it reaches the reference level “R.”

Next, by supplying the vaporized raw material gas to the processing container 10, the liquid level of the liquid raw material 31 gradually decreases. Here, it is assumed that the detection sensor 35b has failed. Specifically, it is assumed that the detection sensor 35b has failed in the ON state. Therefore, at time T2, the controller will not determine that it is the replenishment timing and continue to further supply the vaporized raw material gas to the processing container 10.

Here, the failure determination unit 396 may determine that the detection sensor 35b has failed because the detection results of the detection sensor 35b remains in the ON state, while the detection results of the virtual sensor at the level detection position “L” estimated by the virtual sensor unit 394 switch to the OFF state.

When the failure determination unit 396 determines that the detection sensor 35b has failed, the liquid amount monitor 39 will monitor the liquid level using the virtual sensor at the level detection position “L” estimated by the virtual sensor unit 394.

Through the above processing, as illustrated at time T3 in FIG. 4, the liquid raw material 31 is replenished until the liquid level thereof reaches the reference level “R.” Accordingly, even when at least one of the detection sensors 35a to 35d has failed, the replenishment of the liquid raw material may be realized using the virtual sensors, allowing the gas supply device 30 to continue operating. This may reduce the downtime of the substrate processing apparatus.

Here, the controller 60 may control the replenishment amount so that the remaining amount (liquid amount) of the liquid raw material 31 calculated by the remaining amount calculation unit 393 reaches the liquid amount corresponding to the reference level “R.”

In the example illustrated in FIG. 4, the liquid raw material may be replenished after each substrate processing cycle, as indicated by time zone T4. In this case, the controller 60 replenishes the liquid raw material so that the remaining amount (liquid amount) of the liquid raw material 31 calculated by the remaining amount calculation unit 393 reaches the remaining amount (liquid amount) corresponding to the reference level “R.”

Further, the liquid raw material replenishment operation may also be performed according to the flow illustrated in FIG. 5 using the virtual sensors instead of the actual sensors.

In the example illustrated in FIG. 4, as indicated by time zone T5, whether or not it is the replenishment timing may be determined based on the detection results of the virtual sensors estimated by the virtual sensor unit 394, and the replenishment amount may be controlled based on the detection results of the virtual sensors estimated by the virtual sensor unit 394.

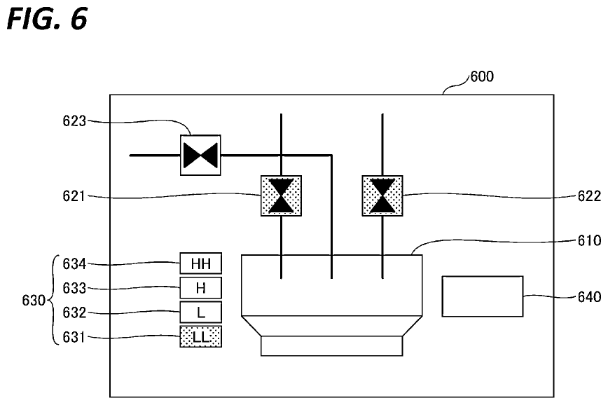

FIG. 6 is an example of a display screen 600 displayed on a display.

The display screen 600 displays an image 610 corresponding to the raw material storage tank 32, an image 621 corresponding to the opening/closing valve 36c, an image 622 corresponding to the opening/closing valve 37b, an image 623 corresponding to the opening/closing valve 38c, an image 630 corresponding to the level sensor 35, and a remaining amount indicator 640.

The image 621 corresponding to the opening/closing valve 36c, the image 622 corresponding to the opening/closing valve 37b, and the image 623 corresponding to the opening/closing valve 38c may switch to enable the determination of the opening/closing status. In the example illustrated in FIG. 6, when the opening/closing valve is open, it is indicated by shaded dots.

The image 630 corresponding to the level sensor 35 includes an image 631 corresponding to the detection sensor 35a, an image 632 corresponding to the detection sensor 35b, an image 633 corresponding to the detection sensor 35c, and an image 634 corresponding to the detection sensor 35d. The images 631 to 634 are adapted to switch according to the detection status of the detection sensors 35a to 35d. In the example illustrated in FIG. 6, when the liquid raw material 31 is detected, it is indicated by shaded dots.

In addition, the images 631 to 634 may indicate the results of actual sensors or virtual sensors.

The remaining amount indicator 640 indicates the remaining amount of the liquid raw material calculated by the remaining amount calculation unit 393 as a numerical value.

According to one aspect, it is possible to provide a method of monitoring a liquid raw material and a gas supply device for monitoring the amount of a liquid raw material stored in a raw material storage tank.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of monitoring a liquid raw material in a gas supply device, the gas supply device comprising:
a raw material storage tank configured to store the liquid raw material;
a liquid level detector configured to detect a liquid level of the liquid raw material stored in the raw material storage tank;
a gas inlet provided in the raw material storage tank and connected to a carrier gas supply that supplies a carrier gas carrying a raw material gas to the raw material storage tank;
a gas outlet provided in the raw material storage tank and connected to a gas discharger that discharges the raw material gas, along with the carrier gas, from the raw material storage tank; and
a raw material inlet provided in the raw material storage tank and connected to a liquid raw material supply that supplies the liquid raw material to the raw material storage tank,
the method comprising:
calculating a remaining amount of the liquid raw material based on a usage amount of the raw material and a replenishment amount of the raw material;
estimating a detection result of a virtual sensor from the remaining amount of the liquid raw material calculated in the calculating; and
monitoring the liquid raw material based on a detection result of the liquid level detector and the detection result of the virtual sensor estimated in the estimating.

2. The method according to claim 1, wherein the usage amount of the raw material is calculated from a time for which the raw material is used and a coefficient related to the raw material.

3. The method according to claim 1, wherein the replenishment amount of the raw material is calculated based on a replenishment flow rate and a replenishment time of the raw material.

4. The method according to claim 1, wherein the remaining amount of the liquid raw material is calculated based on an initial remaining amount value, the usage amount, and the replenishment amount.

5. The method according to claim 1, further comprising:
when the detection result of the liquid level detector does not match with the estimated detection result of the virtual sensor, determining that the liquid level detector has failed.

6. A gas supply device comprising:
a raw material storage tank configured to store a liquid raw material;
a liquid level detector configured to detect a liquid level of the liquid raw material stored in the raw material storage tank;
a gas inlet provided in the raw material storage tank and connected to a carrier gas supply that supplies a carrier gas carrying a raw material gas to the raw material storage tank;
a gas outlet provided in the raw material storage tank and connected to a gas discharger that discharges the raw material gas, along with the carrier gas, from the raw material storage tank;
a raw material inlet provided in the raw material storage tank and connected to a liquid raw material supply that supplies the liquid raw material to the raw material storage tank; and
a liquid amount monitor,
wherein the liquid amount monitor includes:
a usage amount calculator configured to calculate a usage amount of the raw material;
a replenishment amount calculator configured to calculate a replenishment amount of the raw material;
a remaining amount calculator configured to calculate a remaining amount of the liquid raw material;
a virtual sensor configured to estimate a detection result from the remaining amount of the liquid raw material calculated by the remaining amount calculator; and
a failure monitor configured to monitor the liquid raw material based on a detection result of the liquid level detector and the detection result of the virtual sensor.
